(19) United States
(12) Patent Application Publication
(10) Pub. No.: US 2015/0214088 A1
(43) Pub. Date: Jul. 30, 2015

(54) PICKUP METHOD AND PICKUP DEVICE

(71) Applicants: Ken Nakao, Nirasaki City (JP); Michikazu Nakamura, Nirasaki City (JP); Itaru Iida, Nirasaki City (JP); Muneo Harada, Nirasaki City (JP)

(72) Inventors: Ken Nakao, Nirasaki City (JP); Michikazu Nakamura, Nirasaki City (JP); Itaru Iida, Nirasaki City (JP); Muneo Harada, Nirasaki City (JP)

(73) Assignee: TOKYO ELECTRON LIMITED, Tokyo (JP)

(21) Appl. No.: 13/819,033

(22) PCT Filed: Jun. 30, 2011
(86) PCT No.: PCT/JP2011/065058

§ 371 Date: Dec. 5, 2014

(30) Foreign Application Priority Data
Aug. 31, 2010 (JP) 2010-194619

(51) Int. Cl. H01L 21/683; B32B 43/00; H01L 21/67; B25J 15/06

(52) U.S. Cl. CPC H01L 21/6835; B25J 15/0616; B32B 43/006; H01L 21/6838; H01L 21/67011

(57) ABSTRACT

Disclosed is a pickup method in which a first suction unit is caused to approach and come into contact with a chip adhered to an adhesive sheet, and a second suction unit which is formed with a concavity on a contact surface configured to come into contact with the adhesive sheet is caused to approach and come into contact with the adhesive sheet in such a manner as to be opposite to the first suction unit. The adhesive sheet is sucked by the second suction unit that is in contact with the adhesive sheet, and a fluid is injected between the adhesive sheet and the chip by an injection unit. As a result, the adhesive sheet is detached from a portion of the chip opposite to the concavity, and in the state where the chip is being sucked by the first suction unit, the first suction unit is caused to be spaced away from the adhesive sheet that is being sucked by the second suction unit. In this manner, the chip is detached and picked up from the adhesive sheet.

### TECHNICAL FIELD

The present invention relates to a chip pickup method and a chip pickup device.

### BACKGROUND ART

Recently, semiconductor devices have progressed in a highly integrated scale. Here, when a plurality of highly integrated semiconductor devices are arranged in a horizontal plane and connected by wirings for a product, there are concerns about the following issues. That is, one of the concerns is that as the length of the wirings increases, the wiring resistance increases as well, thereby increasing a delay in signal transmission due to the increased length of the wirings.

Therefore, a three-dimensional integration technology has been proposed that stacks a plurality of semiconductor devices to be arranged three-dimensionally. In this three-dimensional integration technology, the following methods are proposed. That is, a substrate formed with a prefabricated integrated circuit is segmented into a plurality of chips. And the chips confirmed as good products through a good product discrimination test performed prior to the segmentation are selected from the plurality of chips obtained by the segmentation. Next, the chips selected in this manner are stacked on a substrate to be mounted as a three-dimensionally stacked structure (which may be referred to as a “stacked chip” below).

Typically, such a stacked chip is fabricated as follows. At first, an adhesive sheet, for example, a dicing tape or a back grind tape is adhered to a substrate formed with semiconductor devices on the side where the semiconductor devices are formed. In addition, the substrate, which has the adhesive sheet adhered to the device formed side of the substrate in this manner, is polished on the opposite side to the device formed side (i.e., on the rear side of the substrate) to make the substrate thin until the substrate has a predetermined thickness. Thereafter, the substrate thinned in this manner is subjected to a dicing in a state where the adhesive sheet is attached to the substrate, thereby being segmented into individual chips. Next, each of the chips segmented in this manner is removed from the adhesive sheet, and the removed chips are stacked one on another (see, for example, Patent Document 1).

Here, during this fabrication process, in the process of removing each of the chips from the adhesive sheet, each of the chips is individually detached and removed from the adhesive sheet by a pickup device. As for such a pick up device, a needle pick up device is disclosed in which a needle is pushed up from the rear side of the adhesive sheet to remove a chip (see, for example, Patent Document 2). In addition, a needless pickup device is disclosed in which a nozzle capable of performing a vacuum suction is caused to approach a surface of a chip, and the chip is removed from an adhesive sheet by the vacuum suction of the nozzle (see, for example, Patent Document 3).

### PRIOR ART DOCUMENT

### Patent Documents

Patent Document 1: Japanese Patent Laid-Open Publication No. 2010-056531

Patent Document 2: Japanese Patent Laid-Open Publication No. S60-102754

Patent Document 3: Japanese Patent Laid-Open Publication No. 2004-039722

### SUMMARY OF INVENTION

### Problems to be Solved by the Invention

However, the following problems may be considered in connection with the pickup device and pickup method that remove (i.e., pick up) each of chips from an adhesive sheet.

That is, when picking up a thinned chip, if the thinned chip is detached from the adhesive sheet within a short time, there is concern that a stress exceeding the material strength of the chip may be applied to the chip, and the chip may be fractured. A method, which may be considered to avoid such a situation, is, for example, to lengthen the time for detaching the chip from the adhesive sheet, thereby reducing the stress applied to the chip when detaching the chip.

However, when the time for detaching the chip from the adhesive sheet is lengthened in this manner, a portion that is detached from the adhesive sheet and a portion that is not detached from the adhesive sheet exist in the surface of the chip at the same time. Therefore, due to the distribution of the portion that is detached from the adhesive sheet and the portion that is not detached from the adhesive sheet, a distribution of stresses applied to the chip occurs in the surface of the chip. Here, there is concern that the chip may be fractured at a portion where the highest stress is applied to the chip in the distribution. That is, when the stress applied to the chip exceeds the fracture strength that is determined by the shape of the chip determined based on the size in plan view and the size in thickness of the chip, and the material strength of the material of the chip, for example, silicon, there is concern that the chip may be fractured.

For example, a shear stress acts on the boundary surface between the portion that is being detached from the adhesive sheet and the portion that is not detached from the adhesive sheet, and the shear stress depends on the shape of the chip that is determined based on the size in plan view and the size in thickness of the chip. In addition, when the shear stress exceeds the shear fracture strength (shear strength) of the chip, the chip may be fractured.

Like this, what is concerned is that merely by lengthening the time for detaching the chip from the adhesive sheet, it may be difficult to prevent the stress applied to the chip by the shape of the chip from being increased over the material strength. Accordingly, there is a problem in that the shape of the chip that allows the chip to be picked up without being fractured is limited.

The present invention has been made in consideration of the problems as described above. That is, the present invention provides a chip pickup method and a chip pickup device that are capable of reducing the stress load applied to a thinned chip when picking up the chip in a state where the chip is adhered to an adhesive sheet, thereby preventing the fracture of the chip in picking up the chip.

### Means for Solving the Problems

In order to solve the problems described above, each of the features to be described below is considered in the present invention.

According to an exemplary embodiment, a pickup method is provided. In the pickup method, a first suction unit is caused to approach and come into contact with a chip adhered to an adhesive sheet, and a second suction unit which is formed with a concavity on a contact surface configured to come into contact with the adhesive sheet is caused to approach and come into contact with the adhesive sheet in such a manner as to be opposite to the first suction unit. In addition, the adhesive sheet is sucked by the second suction unit that is in contact with the adhesive sheet, and a fluid is injected between the adhesive sheet and the chip by an injection unit. As such, the adhesive sheet is detached from a portion of the chip opposite to the concavity, and in the state where the chip is being sucked by the first suction unit, the first suction unit is caused to be spaced away from the adhesive sheet that is being sucked by the second suction unit. In this manner, the chip is detached and picked up from the adhesive sheet.

In addition, according to an exemplary embodiment of the present invention, there is provided a pickup device that includes: a first suction unit that sucks a chip; a first driving unit that drives the first suction unit to be moved; a second suction unit that is formed with a concavity on a contact surface configured to contact with an adhesive sheet, and sucks the adhesive sheet; an injection unit that injects a fluid; and a controller. The controller causes, by the first driving unit, the first suction unit to approach and come into contact with a chip adhered to an adhesive sheet, and causes, by the second driving unit, the second suction unit to approach and come into contact with the adhesive sheet in such a manner as to be opposite to the first suction unit. In addition, the controller causes the second suction unit which is in contact with the adhesive sheet to suck the adhesive sheet, and the injection unit to inject the fluid between the adhesive sheet and the chip, thereby detaching the adhesive sheet from the portion of the chip opposite to the concavity. Further, the controller causes, by the first driving unit, the first suction unit to be spaced away from the adhesive sheet which is being sucked by the second suction unit in the state where the first suction unit is sucking the chip, thereby detaching and picking up the chip from the adhesive sheet.

### Effect of Invention

According to the present invention, even when picking up a thinned chip, the stress load applied to the chip when picking up the chip in the state where the chip is adhered to an adhesive sheet may be reduced, thereby preventing the fracture of the chip.

### BRIEF DESCRIPTION OF DRAWINGS

FIG. 1 is a schematic cross-sectional view of a pickup device according to an exemplary embodiment.

FIG. 2 is a flowchart for describing the sequence of individual processes of a pickup method according to an exemplary embodiment.

FIG. 3A is a schematic cross-sectional view illustrating the state of the pickup device in the individual processes of the pickup method according to the exemplary embodiment (first).

FIG. 3B is a schematic cross-sectional view illustrating the state of the pickup device in the individual processes of the pickup method according to the exemplary embodiment (second).

FIG. 3C is a schematic cross-sectional view illustrating the state of the pickup device in the individual steps of the pickup method according to the exemplary embodiment (third).

FIG. 3D is a schematic cross-sectional view illustrating the state of the pickup device in the individual processes of the pickup method according to the exemplary embodiment (forth).

FIG. 3E is a schematic cross-sectional view illustrating the state of the pickup device in the individual processes of the pickup method according to the exemplary embodiment (fifth).

FIG. 3F is a schematic cross-sectional view illustrating the state of the pickup device in the individual processes of the pickup method according to the exemplary embodiment (sixth).

FIG. 3G is a schematic cross-sectional view illustrating the state of the pickup device in the individual processes of the pickup method according to the exemplary embodiment (seventh).

FIG. 3H is a schematic cross-sectional view illustrating the state of the pickup device in the individual processes of the pickup method according to the exemplary embodiment (eighth).

FIG. 4 is a longitudinal cross-sectional view schematically illustrating a configuration of a pickup device according to a comparative example.

FIG. 5A is a graph illustrating a detaching force applied to a chip versus time in the upper collet lifting process (step S18) in one state among three states.

FIG. 5B is a graph illustrating a detaching force applied to a chip versus time in the upper collet lifting process (step S18) in another state among the three states.

FIG. 5C is a graph illustrating a detaching force applied to a chip versus time in the upper collet lifting process (step S18) in still another state among the three states.

FIG. 6 is a longitudinal cross-sectional view of the pickup device for describing the shear stress applied to the chip in the upper collet lifting process (step S18).

FIG. 7 is a plan view of the chip for describing the shear stress applied to the chip in the upper collet lifting process (step S18).

FIG. 8 is a perspective view of the chip for describing the shear stress applied to the chip in the upper collet lifting process (step S18).

FIG. 9 is a schematic cross-sectional view of a pickup device according to a modified example of the exemplary embodiment.

FIG. 10 is a flowchart for describing the sequence of individual processes of a pickup method according to a modified example of the exemplary embodiment.

FIG. 11A is a schematic cross-sectional view illustrating the state of the pickup device in the individual processes of the pickup method according to the modified example of the exemplary embodiment (first).

FIG. 11B is a schematic cross-sectional view illustrating the state of the pickup device in the individual processes of the pickup method according to the modified example of the exemplary embodiment (second).

FIG. 11C is a schematic cross-sectional view illustrating the state of the pickup device in the individual processes of the pickup method according to the modified example of the exemplary embodiment (third).

FIG. 11D is a schematic cross-sectional view illustrating the state of the pickup device in the individual processes of the pickup method according to the modified example of the exemplary embodiment (forth).

FIG. 11E is a schematic cross-sectional view illustrating the state of the pickup device in the individual processes of the pickup method according to the modified example of the exemplary embodiment (fifth).

### DETAILED DESCRIPTION FOR CARRYING OUT THE INVENTION

Next, the exemplary embodiments of the present invention will be described with reference to the drawings.

### Exemplary Embodiments

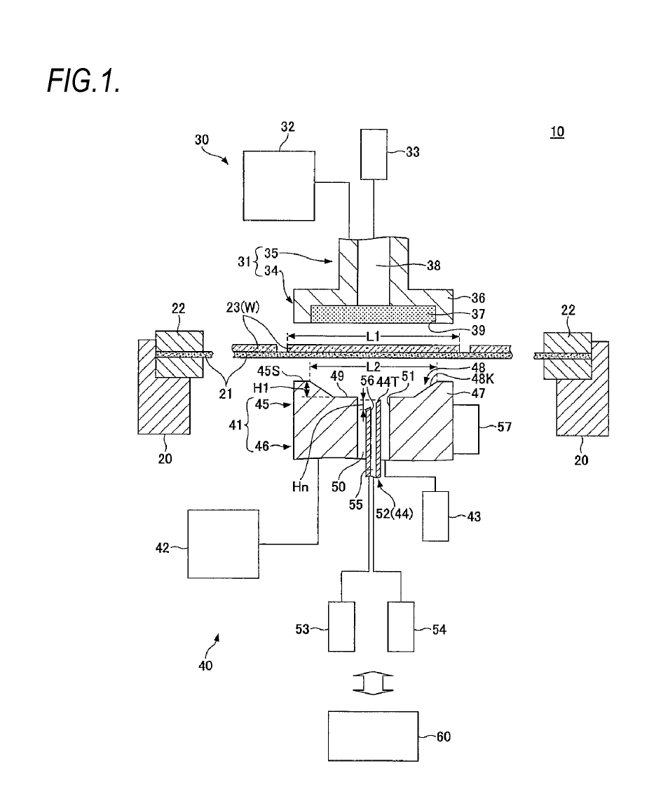

At the beginning, the pickup device and the pickup method according to an exemplary embodiment of the present invention will be described with reference to FIGS. 1 to 8.

At first, the pickup device according to the present exemplary embodiment will be described with reference to FIG. 1. FIG. 1 is a schematic cross-sectional view of a pickup device 10 according to the present exemplary embodiment.

Pickup device 10 includes a stage 20, an upper collet 30, a lower collet 40, and a controller 60.

Stage 20 is installed horizontally. An adhesive sheet 21 to which a wafer W is adhered, for example, a dicing tape, is retained in a ring frame 22 and maintained on stage 20 in that state. Wafer W adhered to adhesive sheet 21 is adhered to adhesive sheet 21 in a state where a plurality of chips 23 formed in wafer W are subjected to a dicing processing and segmented into individual chips.

Meanwhile, stage 20 as being used may be installed separately from pickup device 10. That is, pickup device 10 at least includes upper collet 30 and lower collet 40.

Upper collet 30 and lower collet 40 are configured to sandwich a chip 23 adhered to adhesive sheet 21 maintained on stage 20 from top and bottom surfaces of chip 23, i.e., to be opposite to each other. Upper collet 30 and lower collet 40 are installed in a configuration where each of them is movable in a vertical direction and in a two-dimensional direction in a horizontal plane. Upper collet 30 and lower collet 40 are moved in the vertical direction and in the two-dimensional direction in the horizontal plane by an upper collet driving mechanism 32 and a lower collet driving mechanism 42 to be described later, respectively. In addition, the central axes of upper collet 30 and lower collet 40 are positioned to be aligned with the center of chip 23 to be picked up by upper collet driving mechanism 32 and lower collet driving mechanism 42, respectively.

Meanwhile, upper collet 30 and lower collet 40 correspond to a first suction unit and a second suction unit in the present invention, respectively. In addition, pickup device 10 may take a horizontally laid configuration by rotating the configuration illustrated in FIG. 1 by 90 degrees, or an upside-down configuration of the configuration illustrated in FIG. 1.

Upper collet 30 includes an upper collet body 31, upper collet driving mechanism 32, and an upper collet exhaust mechanism 33. Upper collet driving mechanism 32 corresponds to a first driving unit in the present invention.

Upper collet body 31 includes an upper collet lower end portion 34 and an upper collet shaft portion 35. Upper collet body 31 is a structure attached to the bottom end of upper collet driving mechanism 32, and is configured to be movable in the horizontal plane, and also movable in the vertical direction. In addition, upper collet body 31 is driven by upper collet driving mechanism 32 to be moved in the horizontal plane and to be moved in the vertical direction.

The bottom surface of upper collet lower end portion 34, i.e., the chip 23 side surface, is configured to be substantially parallel to the top surface of chip 23, and has, for example, a rectangular shape, a circular shape or an oval shape, when shown in a plan view. Upper collet lower end portion 34 has a construction where a peripheral edge side member 36 and a center side member 37 are dually arranged at the peripheral edge side and center side of upper collet lower end portion 34, respectively. Peripheral edge side member 36 is an airtightness member, and is formed with an opening 39 at the center side of the bottom surface of peripheral edge side member 36 that is communicated with a suction bore 38 to suck a chip 23 that is contacted with the bottom surface. Center side member 37 is installed to be engaged with the peripheral edge side member 36 in the vicinity of opening 39 that is communicated with suction bore 38. Center side member 37 is formed of a porous material, and has a structure that allows a gas to flow through micro-holes in the porous material.

Upper collet shaft portion 35 retains upper collet lower end portion 34. Upper collet shaft portion 35 has hollow suction bore 38 along the central axis. The lower end of suction bore 38 is connected to opening 39 formed in the bottom surface of peripheral edge side member 36 through center side member 37 formed of the porous material. The top end of suction bore 38 is connected to upper collet exhaust mechanism 33. Upper collet exhaust mechanism 33 includes an exhaust pump and a valve which are not illustrated, and is capable of adjusting an exhaust pressure of suction bore 38 by adjusting the opening extent of the valve at any timing.

When suction bore 38 is decompressed by upper collet exhaust mechanism 33 in a state where the bottom surface of peripheral edge side member 36 is in contact with the top surface of the chip 23, opening 39 is sealed by the top surface of chip 23 such that center side member 37 and suction bore 38 are decompressed. As a result, upper collet body 31 is capable of sucking chip 23. That is, the bottom surface of peripheral edge side member 36 has a structure that isolates center side member 37 formed of the porous material within opening 39 and suction bore 38 from the atmosphere by being contacted with the top surface of chip 23. Accordingly, in the state where chip 23 is sucked to opening 39 formed in upper collet lower end portion 34, upper collet body 31 is moved upward by upper collet driving mechanism 32 to pick up chip 23. Like this, upper collet body 31 may suck and maintain chip 23 even when picking up chip 23.

Lower collet 40 includes a lower collet body 41, lower collet driving mechanism 42, a lower collet exhaust mechanism 43, and a needle 44. Lower collet driving mechanism 42 corresponds to a second driving unit in the present invention.

Lower collet body 41 has a lower collet upper end portion 45 and a lower collet shaft portion 46. Lower collet body 41 is a structure attached to the top end of lower collet driving mechanism 42, and is configured to be movable in a horizontal plane and to be movable in a vertical direction. Meanwhile, stage 20 configured to maintain adhesive sheet 21 to which chip 23 is adhered may occasionally be installed with a configuration that is capable of moving adhesive sheet 21 in the horizontal plane. In such a case, lower collet body 41 may be configured not to be movable in the horizontal plane.

A top surface 45S of lower collet upper end portion 45, i.e., the adhesive sheet 21 side surface is configured to be substantially parallel to a seat surface of adhesive sheet 21, and has, for example, a rectangular shape, a circular shape, or an oval shape when shown in a plan view. Lower collet upper end portion 45 has a peripheral edge side member 47. Peripheral edge side member 47 is an airtightness member, and an opened concavity 48 is formed at the center side of top surface of peripheral edge side member 47. Concavity 48 is used to suck adhesive sheet 21 that is in contact with top surface 45S of peripheral edge side member 47. On a bottom surface 49 of concavity 48, an opening 51 of a suction bore 50 is formed to suck adhesive sheet 21 that is in contact with top surface 45S of peripheral edge side member 47.

Meanwhile, lower collet upper end portion 45 is in contact with adhesive sheet 21 at top surface 45S thereof as described below. Accordingly, top surface 45S of lower collet upper end portion 45 corresponds to a contact surface to be contacted with the adhesive sheet in the present invention.

Lower collet shaft portion 46 maintains lower collet upper end portion 45. Lower collet shaft portion 46 has a hollow suction bore 50 along the central axis. The top end of suction bore 50 is connected to an opening 51 formed in bottom surface 49 of concavity 48. The lower end of suction bore 50 is connected to lower collet exhaust mechanism 43. Lower collet exhaust mechanism 43 has an exhaust pump and a valve which are not illustrated, and is capable of adjusting an exhaust pressure of suction bore 50 by adjusting the opening extent of the valve at any timing.

When suction bore 50 is decompressed by lower collet exhaust mechanism 43 in the state where top surface 45S of peripheral edge side member 47 is in contact with the bottom surface of adhesive sheet 21, concavity 48 and suction bore 50, of which the openings are sealed by the bottom surface of adhesive sheet 21, are decompressed. As a result, lower collet body 41 sucks adhesive sheet 21 to concavity 48. That is, top surface 45S of peripheral edge side member 47 has a structure that isolates concavity 48 and suction bore 40 from the atmosphere by being contacted with the bottom surface of adhesive sheet 21. As a result, even when chip 23 is picked up in the state where chip 23 is sucked to opening 39 formed in upper collet lower end portion 34, lower collet body 41 is capable of sucking and maintaining adhesive sheet 21 by concavity 48. Meanwhile, the pickup of chip 23 is performed by moving upper collet body 3 lupward by upper collet driving mechanism 32 in the state where chip 23 is adsorbed to opening 39 formed in upper collet lower end portion 34.

Needle 44 includes a needle body 52, a needle driving mechanism 53, and a fluid supply mechanism 54. Needle 44 corresponds to an injection unit in the present invention.

Needle 44 is a structure attached to lower collet body 41, and configured to be movable vertically. In addition, needle body 52 is driven by needle driving mechanism 53 to be moved in the vertical direction.

Needle 44 is formed with an opening 56 at a tip end 44T thereof. Opening 56 is communicated with a supply bore 55. Supply bore 55 is provided to supply a fluid in order to inject a fluid of gas or liquid between chip 23 and adhesive sheet 21 detached from chip 23. Needle 44 has a hollow supply bore 55 along the central axis thereof. The top end of supply bore 55 is connected to opening 56 formed in tip end 44T of needle 44. The lower end of supply bore 55 is connected to fluid supply mechanism 54.

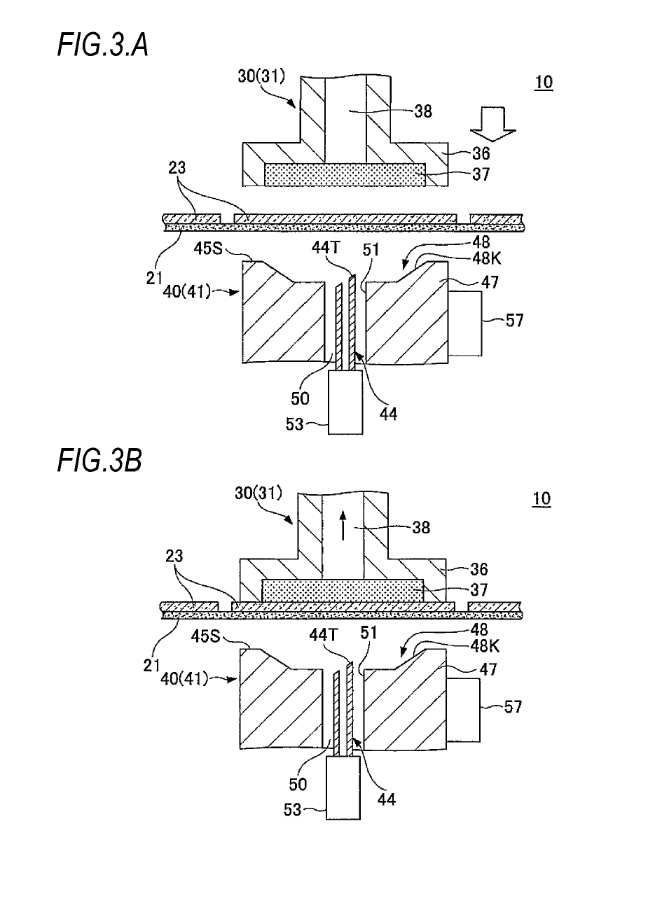

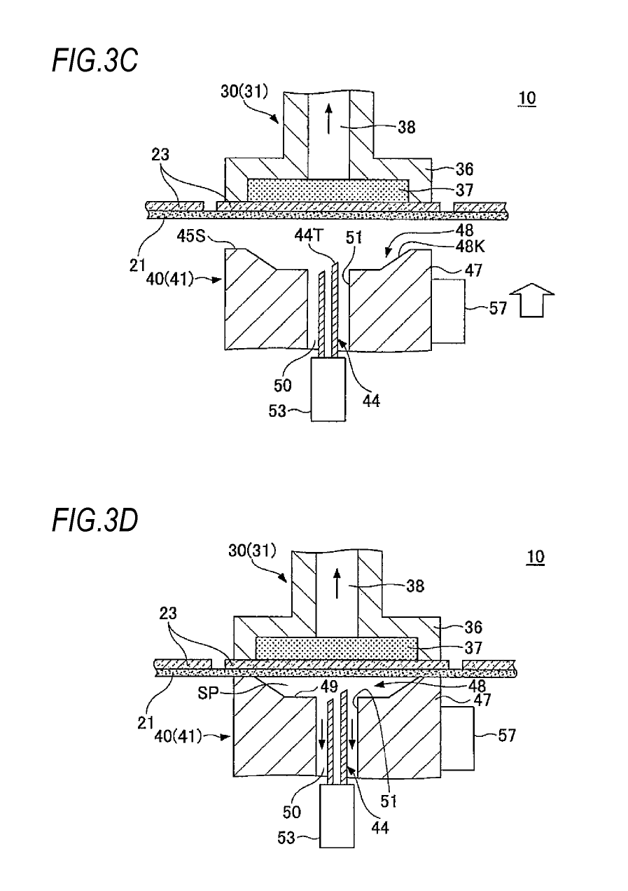

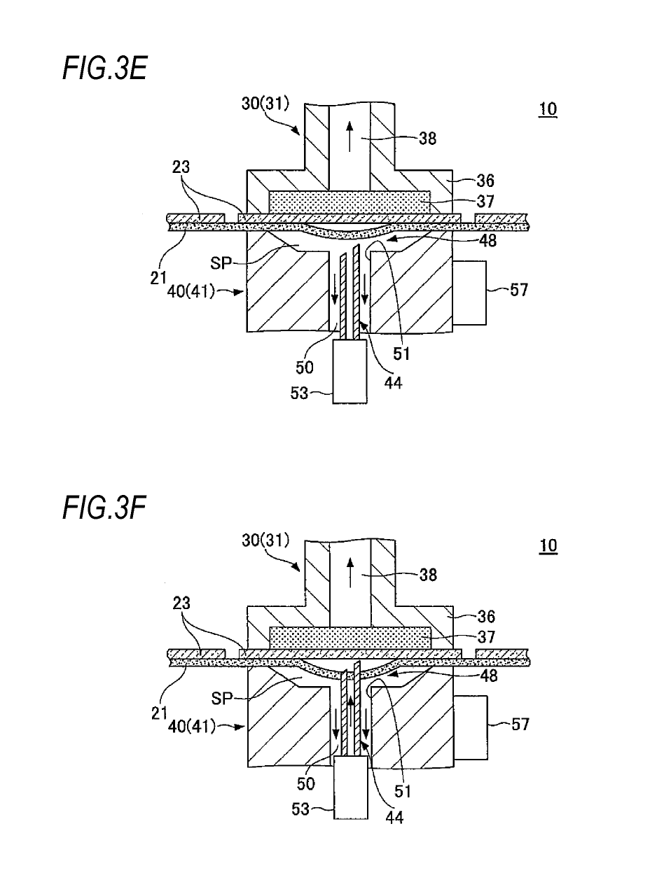

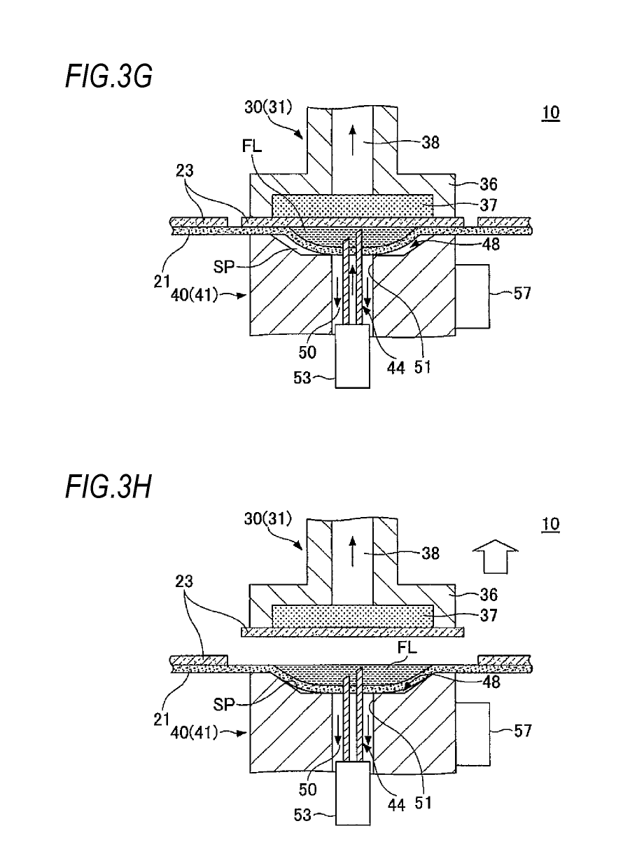

As the bottom surface of adhesive sheet 21 is in contact with top surface 45S of peripheral edge side member 45 as described above, an opening 48K of concavity 48 is blocked up to form a space SP (see FIG. 3D to be described below). Opening 48K of concavity 48 also has, for example, a rectangular shape, a circular shape or an oval shape when shown in the plane view. For example, assuming that chip 23 has a rectangular shape and the shape of opening 48K of concavity 48 is rectangular when shown in a plan view, and that the size in plan view of chip 23 is L1, and the size in plan view of opening 48K of concavity 48 is L2, it is preferable that L2<L1 in order to form space SP. For example, if L1 is 10 mm, L2 may be, for example, 9 mm Meanwhile, as described below, the value of L2 is larger than a predetermined value where a shear stress applied to chip 23 and the shear fracture strength (shear strength) of chip 23 become equal to each other.

Meanwhile, the size in depth H1 of concavity 48 may be a size that allows adhesive sheet 21 to be detached from the bottom surface of chip 23 and to be sucked to concavity 48, and allows needle 44 to be inserted and to inject a fluid between sucked adhesive sheet 21 and the bottom surface of chip 23.

Tip end 44T of needle 44 may have an end face cut by a predetermined taper angle in relation to the horizontal plane such that it can easily penetrate sucked adhesive sheet 21. When the outer diameter of needle 44 is 1 mm φ, and the taper angle is 45°, the height difference Hn between the top end and lower end of the end face is as follows: Hn=1 mm×tan 45°=1 mm. When a margin Hm according to the vertical movement of needle 44 is considered as about 4 mm, concavity 48 preferably has a size in depth H1 of about 5 mm which is the sum of the height difference of end face of needle 44, Hn=1 mm, and the margin, Hm=4 mm

From the foregoing, when the shape of opening 48K is rectangular, concavity 48 may be formed in a truncated pyramid shape where size L2 of opening 48K is 9 mm, and the size in depth is 5 mm. In addition, the shape of opening 48K of concavity 48 may be a circular shape, or an oval shape, in which case concavity 48 may has a truncated cone shape or a truncated elliptic cone shape.

Lower collet body 41 may be provided with a vibration unit 57, for example, an ultrasonic vibrator. When vibration unit 57 is provided, lower collet body 41 is vibrated as vibration unit 57 is vibrated. Accordingly, vibration may be given to adhesive sheet 21 to which chip 23 is adhered by vibrating vibration unit 57 in a state where lower collet body 41 is in contact with chip 23 through adhesive sheet 21. By giving vibration to adhesive sheet 21, vibration is given to the adhesive layer that is provided, for example, on the top surface of adhesive sheet 21 to adhere chip 23, thereby producing a cavitation and hence producing bubbles in the adhesive layer. Further, as bubbles are produced in the adhesive layer, adhesive sheet 21 may be detached from the bottom surface of chip 23.

Meanwhile, a detaching starting process (step S15) may be omitted when it is not difficult to detach adhesive sheet 21 from the surface of chip 23 in a lower collet exhaust process (step S14) as described below. In such a case, vibration unit 57 may be omitted.

Controller 60 controls upper collet driving mechanism 32, upper collet exhaust mechanism 33, lower collet driving mechanism 42, and lower collet exhaust mechanism 43. In addition, when vibration unit 57 is provided, controller 60 also controls vibration unit 57.

Controller 60 may include, for example, a calculation processing unit, a storage unit, and a display unit which are not illustrated. The calculation processing unit may be a computer having, for example, a CPU (Central Processing Unit). The storage unit may be a computer readable recording medium, for example, a hard disc that is recorded with a program that allows the calculation processing unit to execute various processings. The display unit may be, for example, a screen of the computer. The calculation processing unit reads out the program recorded in the storage unit, and sends a control signal to each unit of pickup device 10 according to the program, thereby executing a pickup method according to an exemplary embodiment to be described below.

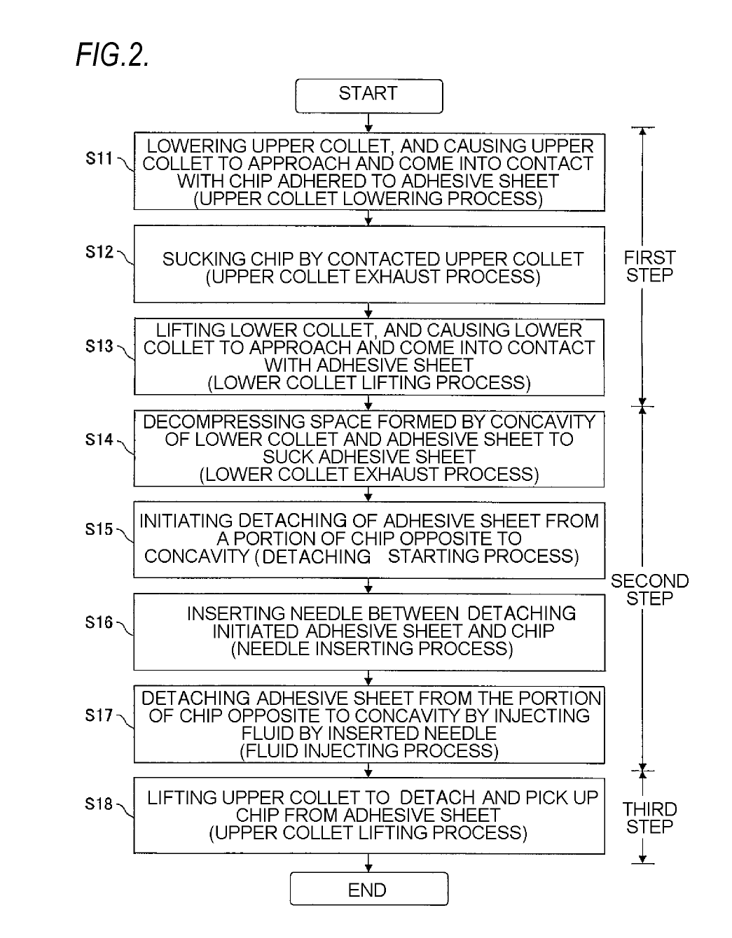

Next, the pickup method according to the present exemplary embodiment will be described with reference to FIGS. 2 to 3H. FIG. 2 is a flowchart for describing the sequence of individual processes of the pickup method according to the present exemplary embodiment. FIGS. 3A to 3H are schematic cross-sectional views illustrating the states of the pickup device in the individual processes of the pickup method of the present exemplary embodiment, respectively.

As illustrated in FIG. 2, the pickup method according to the present exemplary embodiment includes an upper collet lowering process (step S11), an upper collet exhaust process (step S12), a lower collet lifting process (step S13), a lower collet exhaust process (step S14), a peeing starting process (step S15), a needle inserting process (step S16), a fluid injection process (step S17), and an upper collet lifting process (step S18).

Meanwhile, as illustrated in FIG. 2, the processes from the upper collet lowering process (step S11) to the lower collet lifting process (step S13) correspond to the first step in the present invention. In addition, the processes from the lower collet exhaust process (step S14) to the fluid injection process (step S17) correspond to the second step in the present invention. Further, the upper collet lifting process (step S18) corresponds to the third step in the present invention.

Prior to performing the pickup method according to the present exemplary embodiment, a wafer, which is formed with a plurality of chips 23 in advance, is adhered to an adhesive sheet 21, for example, a dicing tape, and the peripheral edge of adhesive sheet 21, to which wafer W is adhered, is retained by, for example, a ring frame 22. In addition, wafer W adhered to adhesive sheet 21 is subjected to a dicing processing by a dicing processing apparatus, which is not illustrated, thereby being segmented into individual chips 23 in the state where chips 23 are adhered to adhesive sheet 21. Further, adhesive sheet 21, to which the plurality of chips 23 subjected to the dicing processing are adhered, is fixedly retained, for example, on a stage 20 in the state where adhesive sheet 21 is retained on ring frame 22. In that event, adhesive sheet 21 may be fixedly retained on stage 20 such that the tape surface of adhesive sheet 21 is horizontally positioned, and horizontally retained top surface of adhesive sheet 21 may be arranged such that chips 23 are adhered to the top surface of adhesive sheet 21.

Meanwhile, the pickup device according to the present exemplary embodiment may be configured as follows. That is, upper collet 30 is caused to approach in the side of adhesive sheet 21 where the chips 23 are adhered thereto. Lower collet 40 is caused to approach in the side of adhesive sheet 21 opposite to the side where the chips 23 are adhered. The pickup device may be configured such that adhesive sheet 21 and a chip 23 are sandwiched between upper collet 30 and lower collet 40 caused to approach in this manner. Accordingly, the upper and lower relationship of upper collet 30 and lower collet 40 is not limited.

At first, the upper collet lowering process (step S11) is performed. At step S11, the upper collet 30 is lowered. In addition, in order to suck and maintain chip 23 as described below, upper collet 30 is caused to approach and come into contact with the top surface of chip 23 adhered to the top surface of fixedly retained adhesive sheet 21. FIG. 3A illustrates the state of pickup device 10 when step S11 is performed.

At step S11, as illustrated in FIG. 3A, the position of upper collet body 31 within a horizontal plane is adjusted in a state where upper collet body 31 is positioned above adhesive sheet 21 fixedly retained, for example, on stage 20. That is, the position of upper collet body 31 within the horizontal plane is adjusted by upper collet driving mechanism 32 as illustrated in FIG. 1 in such a manner that the center of upper collet body 31 and the center of chip 23 are approximately aligned with each other when shown in a plan view. Then, upper collet body 31, of which the position within the horizontal plane is adjusted, is lowered by upper collet driving mechanism 32 such that upper collet body 31 comes into contact with the top surface of chip 23. At this time, peripheral edge side member 36 of upper collet body 31 is in contact with top surface of chip 23. As a result, the airtightness between center side member 37 and suction bore 38 of upper collet body 31 and the top surface of chip 23 is secured.

Meanwhile, the pickup device according to the present exemplary embodiment may be configured such that the upper and lower relationship of upper collet 30 and lower collet 40 is on the contrary to that of FIG. 1, or configured such that upper collet 30 and lower collet 40 are opposite to each other in the horizontal direction. When the pickup device according to the present exemplary embodiment is configured as illustrated, at step S11, upper collet 30 may be caused to approach fixedly retained adhesive sheet 21 and to come into contact with the surface of chip 23 adhered to adhesive sheet 21.

Following step S11, the upper collet exhaust process (step S12) is performed. At step S12, chip 23 is sucked by upper collet 30 that is caused to contact with chip 23 at step S11. FIG. 3B illustrates the state of pickup device 10 when step S12 is performed.

Here, an upper collet exhaust mechanism 33 illustrated in FIG. 1 is connected to suction bore 38 formed in the bottom surface of upper collet body 31. In addition, the inside of center side member 37 and suction bore 38 of upper collet body 31, of which the airtightness is secured in relation to the top surface of chip 23 as illustrated in FIG. 3B, is decompressed by upper collet exhaust mechanism 33. As a result, the top surface of chip 23 is sucked to center side member 37 and suction bore 38 of upper collet body 31.

Meanwhile, step S12 is performed in order to prevent chip 23 from being fractured by shear stress acting on chip 23 in the lower collet exhaust process (step S14). The shear stress applied to chip 23 is that acts on a portion corresponding to the peripheral edge of concavity 48 when space SP formed by concavity 48 of lower collet body 41 and adhesive sheet 21 is decompressed. Accordingly, it would be desirable if step S12 is performed prior to the lower collet exhaust process (step S14).

As described below, depending on the large and small relationship of the area of opening 48K (or the size of opening 48K) of concavity 48 and the area (or the size in a plan view) of chip 23 when shown in a plan view, the shear stress acting on chip 23 at the portion corresponding to the peripheral edge of concavity 48 may not be so high. In such a case, step S12 may be performed prior to the upper collet lifting process (step S18).

Next, the lower collet lifting process (step S13) is performed. At step S13, chip 23 is sandwiched between upper collet 30 and lower collet 40 to be fixedly retained. That is, lower collet 40 is lifted such that, via adhesive sheet 21, lower collet 40 comes into contact with the bottom surface of chip 23 where adhesive sheet 21 is adhered. FIG. 3C illustrates the state of pickup device 10 when step S13 is performed.

At step S13, as illustrated in FIG. 3C, the position of lower collet body 41 in the horizontal plane is adjusted, for example, in the state where lower collet body 41 is positioned below adhesive sheet 21 fixedly retained on stage 20. That is, the position of lower collet body 41 in the horizontal plane is adjusted by lower collet driving mechanism 42 as illustrate in FIG. 1 in such a manner that the center of lower collet body 41 and the center of chip 23 are approximately aligned with each other when viewed from the top. Then, lower collet body 41, of which the position in the horizontal plane is adjusted in this manner, is lifted by lower collet driving mechanism 42 such that lower collet body 41 comes into contact with the bottom surface of chip 23 via adhesive sheet 21. In that event, peripheral edge side member 47 of lower collet body 41 comes into contact with the bottom surface of chip 23 via adhesive sheet 21. As a result, the airtightness of space SP formed in concavity 48 of lower collet body 41 is secured.

As described above, the pickup device according to the present exemplary embodiment may be configured such that the upper and lower relationship of upper collet 30 and lower collet 40 is in contrast to that of FIG. 1, or configured such that upper collet 30 and lower collet 40 are opposite to each other in the horizontal direction. In such a case, at step S13, lower collet 40 may be caused to approach fixedly retained adhesive sheet 21 to be opposite to upper collet 30. In addition, the lower collet 40 caused to approach adhesive sheet 21 in this manner may be caused to come into contact with the surface of chip 23 adhered to adhesive sheet 21, via adhesive sheet 21.

Next, the lower collet exhaust process (step S14) is performed. At step S14, space SP formed by concavity 48 of lower collet 40 and adhesive sheet 21 is decompressed to suck adhesive sheet 21. FIG. 3D illustrates the state of pickup device 10 when step S14 is performed.

As illustrated in FIG. 3D, space SP formed by concavity 48 and adhesive sheet 21 is decompressed by lower collet exhaust mechanism 43 as illustrated in FIG. 1. Here, lower collet exhaust mechanism 43 is connected to opening 51 formed in bottom surface 49 of concavity 48 through suction bore 50. As space SP is decompressed, adhesive sheet 21 adhered to the portion of chip 23 opposite to concavity 48 is sucked toward concavity 48. The degree of decompression may be sufficient if suction by the decompression causes adhesive sheet 21 to be detached from chip 23.

However, depending on the degree of decompression, adhesive sheet 21 may occasionally be difficult to be detached from the surface of chip 23. In such a case, the peeing starting process (step S15) may be performed in order to produce an initiating point to detach adhesive sheet 21 from the surface of chip 23. At step S15, the detaching of adhesive sheet 21 from the portion of chip 23 opposite to concavity 48 is started by vibrating adhesive sheet 21. FIG. 3E illustrates the state of pickup device 10 when step S15 is performed.

At step S15, vibration is given to adhesive sheet 21 by vibrating the above-described vibration unit 57. In this manner, vibration is given to the adhesive layer that is provided, for example, on adhesive sheet 21, thereby producing a cavitation and hence producing bubbles in the adhesive layer. Here, the adhesive layer is that provided to adhere chip 23 to the top surface of adhesive sheet 21. Meanwhile, at step S14, space SP formed by concavity 48 and adhesive sheet 21 is decompressed. Accordingly, as illustrated in FIG. 3E, the detaching of adhesive sheet 21 may be initiated from the portion of chip 23 opposite to concavity 48.

Next, the needle inserting process (step S16) is performed. At step S16, when the detaching of adhesive sheet 21 is initiated from the portion of chip 23 opposite to concavity 48, needle 44 is inserted between chip 23 and detaching initiated adhesive sheet 21. FIG. 3F illustrates the state of pickup device 10 when step S16 is performed.

In the present exemplary embodiment, needle 44 is installed to be movable in a direction parallel to the depth direction of concavity 48 within suction bore 50, i.e., to be movable vertically within suction bore 50 by needle driving mechanism 53 as illustrated in FIG. 1. Accordingly, needle 44 is lifted by needle driving mechanism 53, penetrated through detached adhesive sheet 21 as illustrated in FIG. 3F, and inserted between chip 23 and detached adhesive sheet 21.

Next, the fluid injection process (step S17) is performed. At step S17, a fluid FL is injected between chip 23 and detached adhesive sheet 21 by needle 44 inserted at step S16. As a result, adhesive sheet 21 may be detached from a larger area in the portion of chip 23 opposite to concavity 48. FIG. 3G illustrates the state of pickup device 10 when step S17 is performed.

At step S17, as illustrated in FIG. 3G, fluid FL including a gas or a liquid is injected between chip 23 and detached adhesive sheet 21 by needle 44 inserted between chip 23 and detached adhesive sheet 21. As a result, the following forces act on detached adhesive sheet 21. That is, the pressure of fluid FL injected between chip 23 and detached adhesive sheet 21, and the suction force sucking detached adhesive sheet 21 to concavity 48 act on detached adhesive sheet 21. As a result, a force tending to further detach adhesive sheet 21 from chip 23 acts such that adhesive sheet 21 can be completely detached from the portion of chip 23 opposite to concavity 48.

An incompressible fluid which is a liquid or a compressible derivative which is a gas may be used as fluid FL. A liquid state fluid including one or more of, for example, a water such as pure water, an alcohol such as ethanol, a carbonated water may be used as the incompressible fluid. In addition, a gas state fluid including one or more of, for example, carbon dioxide (CO₂), nitrogen (N₂), and other various gases may be used as the compressible derivative.

Next, the upper collet lifting process (step S18) is performed. At step S18, upper collet 30 is lifted in the state where fluid FL is injected between detached adhesive sheet 21 and chip 23 (see, e.g., FIG. 3G). Then, as upper collet 30 is caused to be spaced away from adhesive sheet 21 sucked by lower collet 40 in this manner, chip 23 is detached from adhesive sheet 21. FIG. 3H illustrates the state of pickup device 10 when step S18 is performed.

Step S18 is performed in the state where adhesive sheet 21 is detached from the portion of chip 23 opposite to concavity 48, fluid FL is injected between detached adhesive sheet 21 and chip 23, and chip 23 is sucked (see, e.g., FIG. 3G). That is, at step S18, upper collet body 31 is lifted by upper collet driving mechanism 32 illustrated in FIG. 1 from this state. As upper collet body 31 is lifted in this manner, chip 23 sucked to upper collet 30 is detached and picked up from adhesive sheet 21 as illustrated in FIG. 3H.

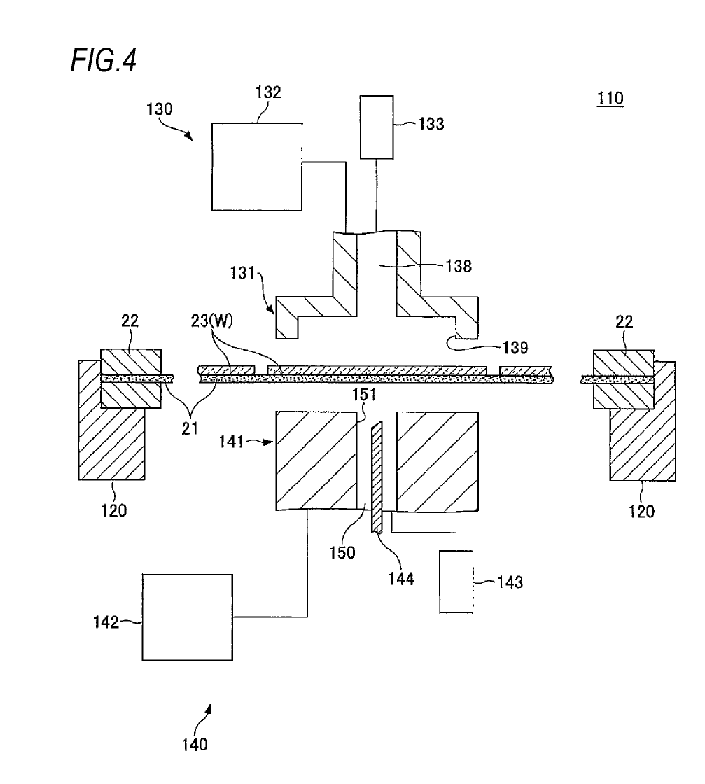

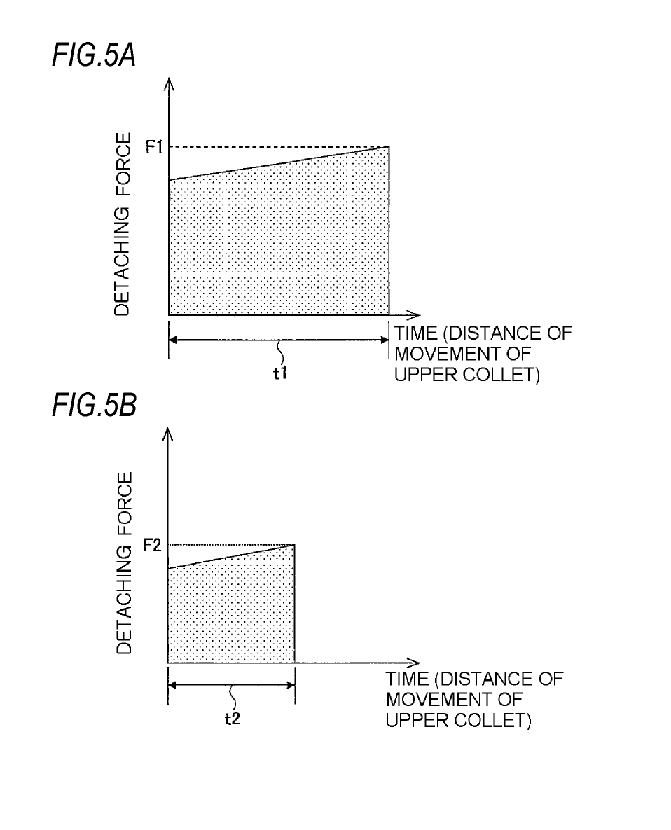

Next, descriptions will be made as to acting effects capable of reducing a stress load applied to a chip when the chip adhered to an adhesive sheet by the pickup device and pickup method according to the present exemplary embodiment with reference to FIGS. 4 and 5A to 5C.

Typically, as methods for investigating an adhesive force of an adhesive sheet, i.e., an adhesive tack characteristic, an inclined ball tack test, a rolling ball tack test, and a probe tack test are known. For example, in the probe tack test, a flat end face of a cylindrical probe is brought into contact with a surface of an adhesive, and then a stress-deformation curve per unit area when the probe is removed is measured. In addition, the adhesive force can be calculated, for example, from the maximum stress σₘₐₓ per unit area in the stress-deformation curve.

Accordingly, a detaching force F required for detaching the chip from the adhesive sheet in the upper collet lifting process (step S18) of the pickup method according to the present exemplary embodiment is expressed as follows.

F=S×σₘₐₓ (1)

Here, S indicates the adhered area between the chip and the adhesive sheet at the time when the upper collet lifting process (step S18) is initiated.

When an ordinary pressure-sensitive series of Toyo Adtech Co., Ltd. are used as a dicing tape, the adhesive force by the probe tack method (i.e., a detaching force F) is 0.7 N/20 mm² to 1.0 N/20 mm². In addition, when a UV series of Toyo Adtech Co., Ltd. is used as a dicing tape, the adhesive force by the probe tack method (i.e., a detaching force F) is 1.7 N/20 mm² to 3.9 N/20 mm².

Now, for the convenience of description, a pickup device in which no concavity is formed on the top surface of the lower collet, and the needle is configured such that it cannot inject a fluid will be described as a comparative example. FIG. 4 is a longitudinal cross-sectional view schematically illustrating a configuration of a pickup device 110 according to the comparative example.

As illustrated in FIG. 4, a pickup device 110 according to the comparative example includes a stage 120, an upper collet 130, and a lower collet 140. Upper collet 130 includes an upper collet body 131, an upper collet driving mechanism 132, and an upper collet exhaust mechanism 133. Lower collet 140 includes a lower collet body 141, a lower collet driving mechanism 142, a lower collet exhaust mechanism 143, and a needle 144. Like the exemplary embodiment described above with reference to, for example, FIG. 1, an adhesive sheet 21, to which chips 23 are adhered, is retained on a stage 120 through a ring frame 22. In addition, a suction bore 138 communicated with an opening 139 formed in the bottom surface of upper collet body 131 is decompressed by upper collet exhaust mechanism 133, which is also the same as the exemplary embodiment described with reference to, for example, FIG. 1. Further, a suction bore 150 communicated with an opening 151 formed in the top surface of lower collet body 141 is decompressed by lower collet exhaust mechanism 143, which is also the same as the exemplary embodiment described above with reference to, for example, FIG. 1.

However, in pickup device 110 according to the comparative example, as illustrated in FIG. 4, no concavity is formed in the top surface of lower collet body 141. In addition, needle 144 is installed to freely protrude from the top surface of lower collet body 141 beyond opening 151 formed in the top surface of lower collet body 141. However, fluid cannot be injected by needle 144.

Here, in pickup device 110 according to the comparative example, it is assumed that chip 23 is sucked by decompressing suction bore 138 of upper collet body 131, and adhesive sheet 21 is sucked by decompressing suction bore 150 of lower collet body 141. In addition, it is also assumed that the detaching force required for detaching chip 23 from adhesive sheet 21 by lifting upper collet body 131 in this state is F1.

Meanwhile, in pickup device 10 according to the exemplary embodiment described above with reference to, for example, FIG. 1, what is presumed is a state where the amount of injected fluid FL is relatively small when the fluid injection process (step S17) is performed. In addition, it is assumed that the detaching force required for detaching chip 23 from adhesive sheet 21 by lifting upper collet body 31 in this state is F2. In addition, in pickup device 10 according to the exemplary embodiment described above with reference to, for example, FIG. 1, what is presumed is a state where the amount of injected fluid FL is relatively large. Further, it is assumed that the detaching force required for detaching chip 23 from adhesive sheet 21 by lifting upper collet body 31 in this state is F3. Then, a relationship of F1>F2>F3 is established.

The graphs of detaching force acting on chip 23 versus time in the upper collet lifting process (step S18) in the above-described three states are illustrated in FIGS. 5A to 5C, respectively. Here, FIG. 5A illustrates the case of the comparative example described with reference to FIG. 4. FIG. 5B illustrates the case where the amount of injected fluid FL is relatively small in the exemplary embodiment described above with reference to, for example, FIG. 1. FIG. 5C illustrates the case where the amount of injected fluid FL is relatively large in the exemplary embodiment described above with reference to, for example, FIG. 1. In addition, in FIGS. 5A to 5C, it was assumed that upper collets 30, 130 are lifted at a constant velocity. Therefore, the horizontal axis in each of FIGS. 5A to 5C is equivalent to the distance of movement of each of upper collets 30, 130 in the upward direction.

Upon comparing the three cases of FIGS. 5A to 5C, in the case where the adhesion area of chip 23 and adhesive sheet 21 is the largest at the initiation of the upper collet lifting process (step S18), i.e., in the case of FIG. 5A, detaching force F1 is the maximum. In this case, the time required for detaching, t1, i.e., the distance of movement of upper collet 130 is also the maximum. In addition, in the case where the adhesion area of chip 23 and adhesive sheet 21 is the smallest at the initiation of the upper collet lifting process (step S18), i.e., in the case of FIG. 5C, detaching force F3 is the minimum. In this case, the time required for detaching, t3, i.e., the distance of movement of upper collet 30 is also the minimum. Further, in the case as illustrated in FIG. 5B, detaching force F2 is in the middle of F1 and F3, and the time required for detaching, t2, is also in the middle of t1 and t3.

That is, in the exemplary embodiment described with reference to, for example, FIG. 1, adhesive sheet 21 is sucked to concavity 48 by lower collet 40 (step S14) prior to detaching chip 23 from adhesive sheet 21 in the upper collet lifting process (step S18). In addition, fluid FL is injected between adhesive sheet 21 and chip 23 by needle 44 (step S17). In this manner, adhesive sheet 21 is detached from the portion of chip 23 opposite to concavity 48. As such, the adhesion area of chip 23 and adhesive sheet 21 when initiating the upper collet lifting process (step S18) may be reduced. As a result, detaching force F in the upper collet lifting process (step S18) is reduced, thereby shortening the time required for detaching t.

Next, descriptions will be made as to an acting effect capable of suppressing a chip from being fractured when the chip adhered to an adhesive sheet is picked up by the pickup device and pickup method according to the exemplary embodiment described above with reference to, for example, FIG. 1.

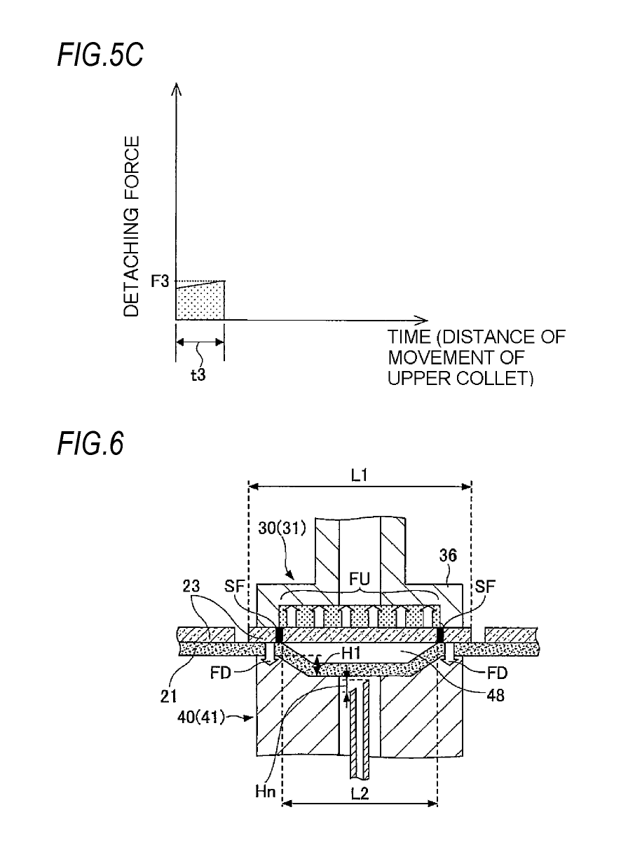

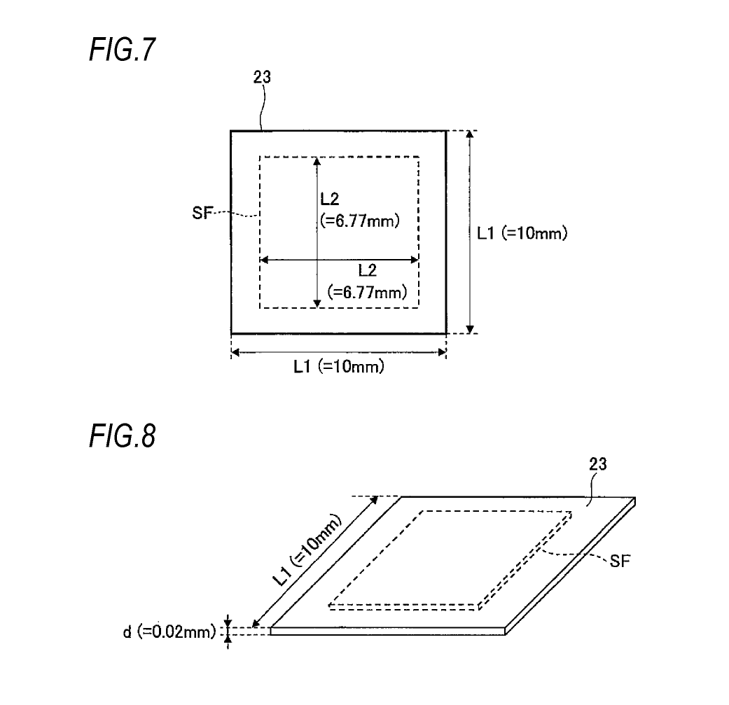

FIG. 6 is a longitudinal cross-sectional view of pickup device 10 for describing the shear stress acting on chip 23 in the upper collet lifting process (step S18). FIG. 7 is a plan view of chip 23 for describing the shear stress acting on chip 23 in the upper collet lifting process (step S18). FIG. 7 is a perspective view of chip 23 for describing a shear area of the shear stress acting on chip 23 in the upper collet lifting process (step S18).

Meanwhile, hereinbelow, descriptions will be made as to the state where the possible maximum amount of fluid F1 is injected in the fluid injection process (step S17). In this state, adhesive sheet 21 is completely detached from chip 23 in the portion of chip 23 opposite to concavity 48, and as illustrated in FIG. 5C, detaching force (detaching resistance) F in the upper collet lifting process (step S18) becomes the minimum.

As illustrated in FIG. 6, in the upper collet lifting process (step S18), an upward suction force FU by upper collet acts on the portion of chip 23 opposite to concavity 48. In addition, a downward suction force FD by adhesive sheet 21 acts on the portion other than the portion of chip 23 opposite to concavity 48. In that event, assuming that the shear force acting on the boundary between the portion of chip 23 opposite to concavity 48 and the portion other than the portion of chip 23 opposite to concavity 48, i.e., a face SF in FIGS. 6 to 8 (hereinbelow, referred to as a “shear face”) is T, and the downward is plus (+), shear force T is expressed as follows.

T=FD−FU (2)

In addition, assuming that the sum of areas of shear faces SF is A, the shear stress τ when shear force T acts on shear faces SF is expressed as follows.

τ=T/A=(FD−FU)/A (3)

In addition, assuming that the shear fracture strength of chip is τₘₐₓ, a condition where chip 23 is not fractured is that shear stress τ and shear fracture strength τₘₐₓ satisfy the following relationship.

τ<τmax (4)

Next, shear stress τ of chip 23 is estimated. Hereinbelow, as illustrated in FIGS. 7 and 8, it is assumed that the shape of chip 23 when shown, for example, in a plan view is a square shape, of which each side (plan view size) is L1, and the thickness is d. In addition, as illustrated in FIG. 7, it is assumed that the shape of concavity 48 of lower collet 40 when shown in the plan view is a square shape, of which each side (the size of the opening) is L2. For the purpose of simplification, the shape of peripheral edge side member 36 of upper collet 30 and the shape of chip 23 when shown in the plan view are substantially the same, and upward suction force FU is small as compared to downward suction force FD.

Then, from FIGS. 7 and 8,

A=L2×d×4 (5)

In addition, from Equation 1,

FD−FU≈FD=(L1²−L2²)×σₘₐₓ (6)

In addition, from Equations 3, 5 and 6,

τ=(L1²−L2²)×σₘₐₓ/(L2×d×4) (7)

Based on the physical property of the above-mentioned dicing tapes, the maximum stress σₘₐₓ is expressed as follows.

σₘₐₓ=0.05 N/mm² (8)

In addition, based on the description of “Investigating the Influence of Fabrication Process and Crystal Orientation on Shear Strength of Silicon Microcomponents”, Q. Chen, D.-J. Yao, C.-J. Kim, and G. P. Carman, Journal of Materials Science, Vol. 35, No. 21, November 2000, pp. 5465-5474, the shear fracture strength τₘₐₓ is as follows.

τₘₐₓ=5 MPa

In addition, plan view size L1 and thickness d of chip 23 are as follows.

L1=10 mm (9)

d=0.02 mm (10)

After assuming the above numerical values, the relationships of opening 48K of concavity 48 with shear stress τ and shear fracture strength were calculated while changing size L2 of opening 48K to 5 mm, 6.7 mm, 8 mm and 9 mm. The results are represented in Table 1.

TABLE 1

| | | | | |
|---|---|---|---|---|
| Opening size of | 5 | 6.7 | 8 | 9 |
| concavity L2 (mm) | | | | |
| Shear stress τ (MPa) | 9.4 | 5 | 2.8 | 1.3 |
| As compared to | Larger | Equal | Smaller | Smaller |
| shear fracture | (Fractured) | (Fractured) | (Not | (Not |
| strength τₘₐₓ | | | fractured) | fractured) |

As represented in Table 1, when size L2 of opening 48K of concavity 48 is equal to or less than 6.7 mm, shear stress τ acting on shear faces SF is not smaller than shear fracture strength τₘₐₓ. As a result, there is concern that chip 23 may be fractured by shear in the upper collet lifting process (step S18). Meanwhile, when size L2 of opening 48K of concavity 48 is larger than 6.7 mm, shear stress τ acting on shear faces SF becomes smaller than shear fracture strength τₘₐₓ. As a result, there is no concern that chip 23 may be fractured by shear in the upper collet lifting process (step S18). That is, when size L2 of opening 48K of concavity 48 is smaller than plan view size L1 of chip 23, and larger than a predetermined value, shear stress τ acting on shear faces SF may be set to be smaller than shear fracture strength τₘₐₓ. As a result, the shear fracture of chip 23 in the upper collet lifting process (step S18) may be suppressed.

That is, in the present exemplary embodiment, size L2 of opening 48K of concavity 48 may be set to be larger than the predetermined value, and to be smaller than the size in plan view L1 of chip 23. Here, the predetermined value means the value of size L2 of opening 48K of concavity 48 when shear stress acting on chip 23 when upper collet 30 is lifted in the upper collet lifting process (step S18) becomes equal to shear fracture strength (shear strength) of chip 23. Like this, by setting size L2 of opening 48K of concavity 49 to be larger than the predetermined value and to be smaller than the size in plan view L1 of chip 23, it is possible to suppress chip 23 from being fractured when chip 23 adhered to adhesive sheet 21 is picked up.

In particular, as being obvious from Equation 7, when thickness d of chip 23 is reduced, shear stress τ is increased. Even in such a case, in the present invention, shear stress τ expressed by Equation 7 may be reduced by adjusting size L2 of opening 48K of concavity 48 to be increased. Accordingly, in the present exemplary embodiment, even when a chip 23 with a reduced thickness d is picked up, it is possible to suppress chip 23 from being fractured.

### Modified Example of Exemplary Embodiment

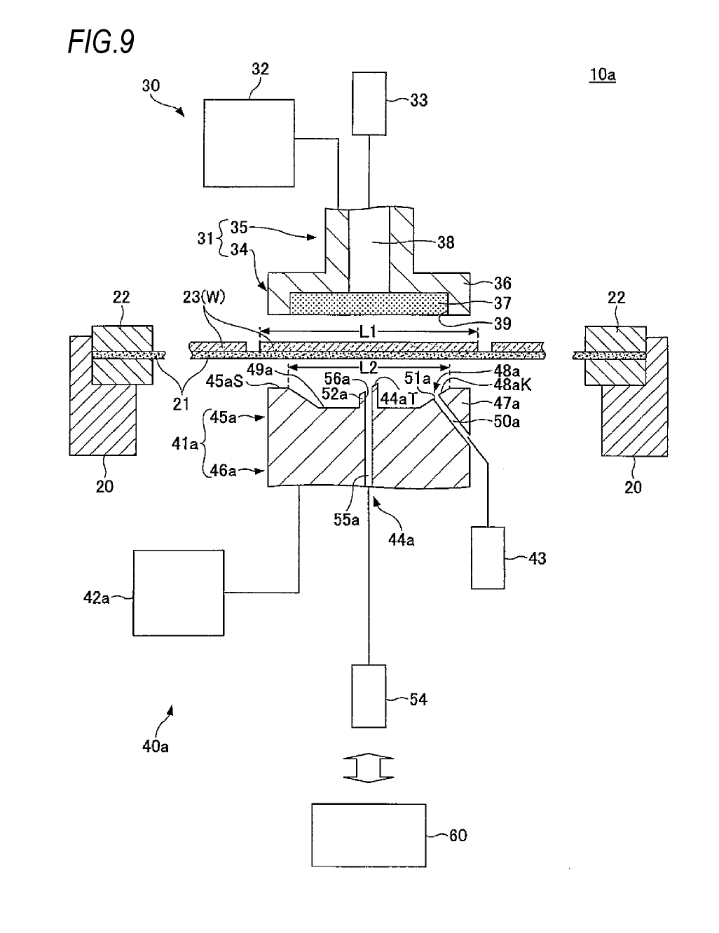

Next, a pickup device and pickup method according to a modified example of the exemplary embodiment of the present invention will be described with reference to FIGS. 9 to 11E.

At first, the pickup device according to the modified example will be described with reference to FIG. 9. FIG. 9 is a schematic cross-sectional view of a pickup device 10a according to the modified example.

Pickup device 10a according to the modified example is differentiated from pickup device 10 according to the exemplary embodiment described above with reference to, for example, FIG. 1 in the following points. That is, in pickup device 10a according to the modified example, a needle 44a is installed integrally with a lower collet 40a in the state where a tip end 44aT of needle 44a protrudes from a bottom surface 49a of a concavity 48a of lower collet 40a.

As in the exemplary embodiment described above with reference to, for example, FIG. 1, pickup device 10a according to the modified example includes an upper collet 30, lower collet 40a, and a controller 60. In addition, upper collet 30 and controller 60 in the modified example may be the same in construction as upper collet 30 and controller 60 in the exemplary embodiment described above with reference to, for example, FIG. 1. In FIG. 9, the same components as those of pickup device 10 according to the exemplary embodiment described with reference to, for example, FIG. 1 are denoted by the same reference symbols, and the descriptions thereof will be omitted.

Meanwhile, although lower collet 40a in the modified example includes a lower collet body 41a, a lower collet driving mechanism 42a, a lower collet exhaust mechanism 43, and needle 44a, the configurations of lower collet body 41a and needle 44a are different from those of the exemplary embodiment described above with reference to, for example, FIG. 1.

As in the exemplary embodiment described above with reference to, for example, FIG. 1, lower collet body 41a includes a lower collet upper end portion 45a, and a lower collet shaft portion 46a, and lower collet upper end portion 45a includes a peripheral edge side member 47a. In addition, as in the exemplary embodiment described above with reference to, for example, FIG. 1, an opened concavity 48a is formed at the center side of a top surface 45aS of peripheral side member 47a to suck adhesive sheet 21 that is in contact with top surface 45s.

However, in the modified example, needle 44a only has a needle body 52a and a fluid supply mechanism 54. That is, needle 44a is installed integrally with lower collet body 41a in the state where tip end 44aT of needle 44a protrudes from a bottom surface 49a of concavity 48a of lower collet body 41a, and is not installed to be movable in the vertical direction in relation to lower collet body 41a.

Therefore, a suction bore 50a of lower collet body 41a may not allow needle 44a to movably penetrate in the vertical direction therethrough. Accordingly, the suction bore 50a may be formed to have an opening 51a at a portion other than the portion of concavity 48a where needle body 52a is installed, as in the example illustrated in FIG. 9. In the example illustrated in FIG. 9, opening 51a of suction bore 50a is not formed at the center of bottom surface 49a of concavity 48a, but formed at the peripheral edge of bottom surface 49a.

Meanwhile, as in the exemplary embodiment described above with reference to, for example, FIG. 1, a supply bore 55a is formed in needle body 52a and communicated with an opening 56a formed at tip end 44aT of needle body 52a.

Lower collet body 41 may be provided with a vibration unit like the exemplary embodiment described above with reference to, for example, FIG. 1. However, an example that is not provided with the vibration unit as illustrated in FIG. 9 will be described below.

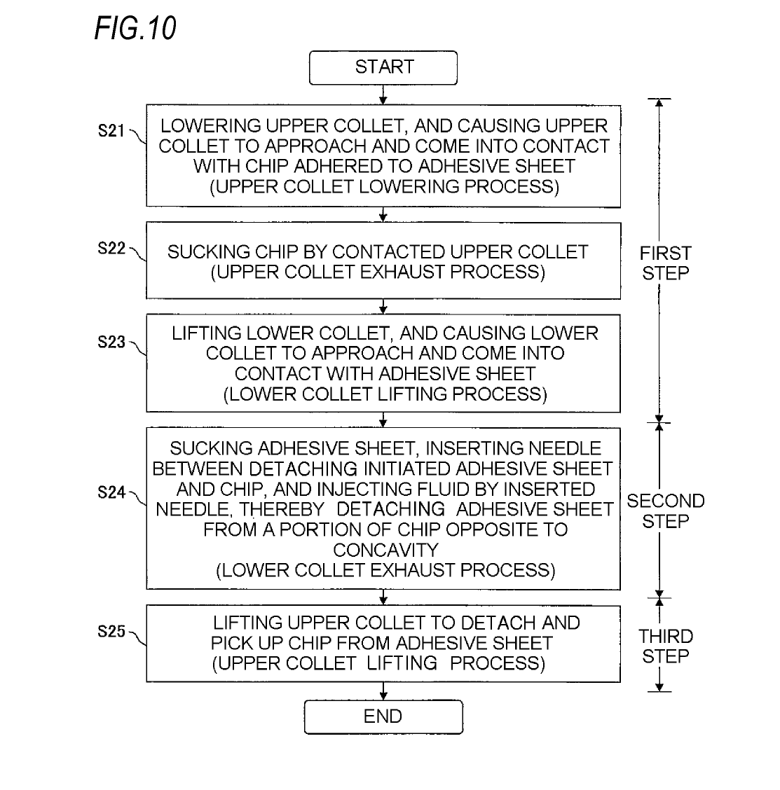

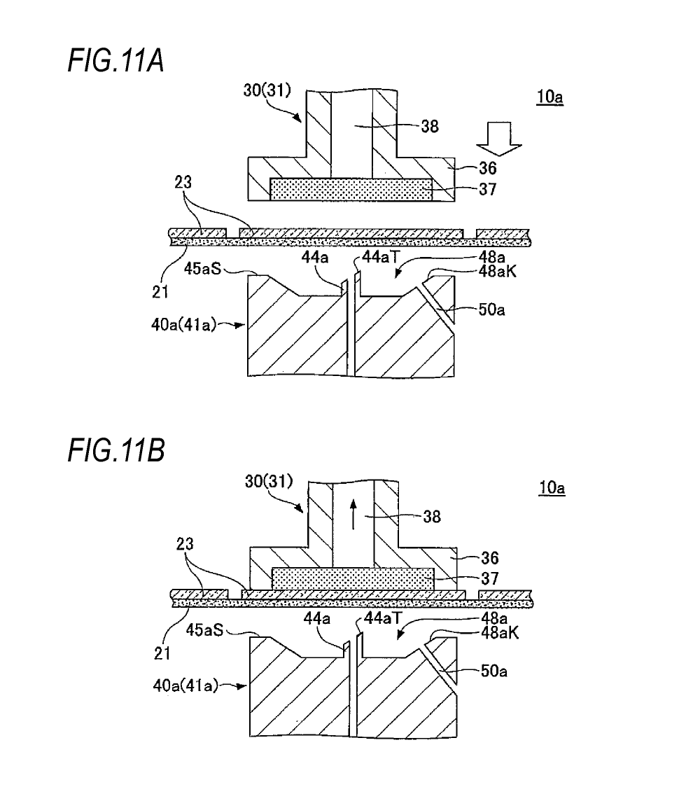

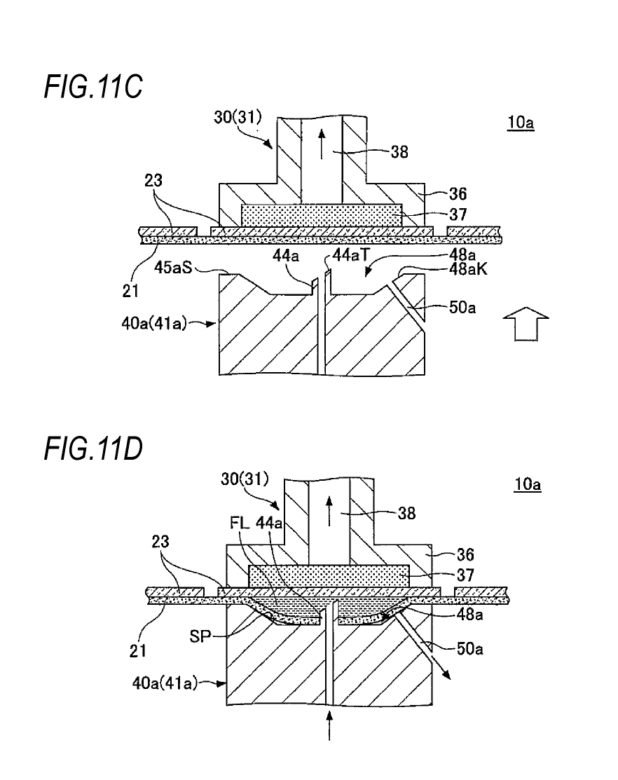

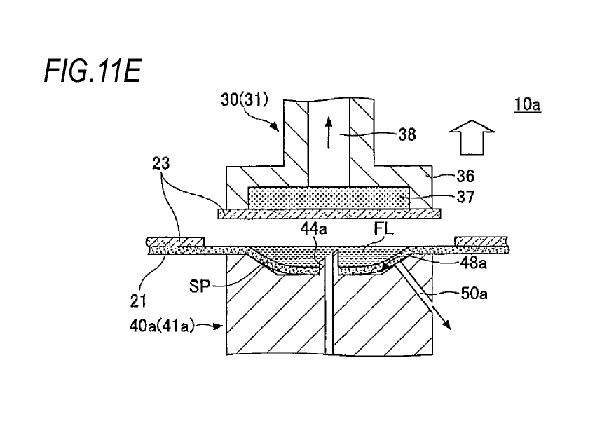

Next, the pickup method according to the modified example described above with reference to FIG. 9 will be described below with reference to FIGS. 10 to 11E. FIG. 10 is a flowchart for describing the sequence of individual processes of the pickup method according to the modified example. FIGS. 11A to 11F are schematic cross-sectional views that illustrate the states of pickup device 10a in the individual processes of the pickup method according to the modified example, respectively.

As illustrated in FIG. 10, the pickup method according to the modified example includes an upper collet lowering process (step S21), an upper collet exhaust process (step S22), a lower collet lifting process (step S23), a lower collet exhaust process (step S24), and an upper collet lifting process (step S25).

Meanwhile, as illustrated in FIG. 10, the processes from the upper collet lowering process (step S21) to the lower collet lifting process (step S23) correspond to the first step in the present invention. In addition, the lower collet exhaust process (step S24) corresponds to the second step in the present invention. Further, the upper collet lifting process (step S25) corresponds to the third step in the present invention.

As in the exemplary embodiment described above with referenced to, for example, FIG. 1, a process of fixedly retaining adhesive sheet 2, to which chip 23 is adhered in advance, on stage 20 is performed prior to performing the pickup method according to the modified example. In addition, the upper collet lowering process (step S21), the upper collet exhaust process (step S22), and the lower collet lifting process (step S23) of the pickup method according to the modified example are the same as the upper collet lowering process (step S11), the upper collet exhaust process (step S12), and the lower collet lifting process (step S13) of the pickup method according to the exemplary embodiment described with reference to, for example, FIG. 1. FIGS. 11A to 11C illustrates the states of pickup device 10a when performing the upper collet lowering process (step S21), the upper collet exhaust process (step S22), and the lower collet lifting process (step S23), respectively.

Following the upper collet lowering process (step S21), the upper collet exhaust process (step S22), and the lower collet lifting process (step S23), the lower collet exhaust process (S24) is performed. At step S24, a space SP formed by concavity 48a of lower collet 40a and adhesive sheet 21 is decompressed to suck adhesive sheet 21. FIG. 11D illustrates the state of pickup device 10a when step S24 is performed.

As illustrated in FIG. 11D, space SP formed by concavity 48a and adhesive sheet 21 is decompressed by lower collet exhaust mechanism 43 connected to suction bore 50a formed in concavity 48a and illustrated in FIG. 9. Therefore, adhesive sheet 21 adhered to the portion of chip 23 opposite to concavity 48a is sucked to concavity 48a. The degree of decompression of space SP may be sufficient if the suction by the decompression causes adhesive sheet 21, which is adhered to the portion of chip 23 opposite to concavity 48a, to be detached from chip 23.

In the lower collet exhaust process (step S24), adhesive sheet 21 is sucked to concavity 48a by the decompression of space SP, and thus adhesive sheet 21 adhered to the portion of chip 23 opposite to concavity 48a is detached. In that event, needle 44a is inserted through detached adhesive sheet 21. In practice, the height of needle 44a protruding from bottom surface 49a of concavity 48a may be designed according to the suction force that sucks adhesive sheet 21 by suction bore 50a decompressed by lower collet exhaust mechanism 43.

In addition, in the lower collet exhaust process (step S24), fluid FL is injected between chip 23 and detached adhesive sheet 21 by needle 44a inserted as described above. As such, adhesive sheet 21 is detached from wider area in the portion of chip 23 opposite to concavity 48a.

That is, in the modified example, the lower collet exhaust process (step S14), the needle inserting process (step S16), and the fluid injection process (step S17) in the pickup method according to the exemplary embodiment described above with reference to, for example, FIG. 1 are performed simultaneously (step S24).

Following the lower collet exhaust process (step S24), the upper collet lifting process (step S25) is performed. The upper collet lifting process (step S25) may be performed like the upper collet lifting process (step S18) in the exemplary embodiment described above with reference to, for example, FIG. 1. FIG. 11E illustrates the state of pickup device 10a when step S25 is performed.

Also in the modified example, prior to detaching chip 23 from adhesive sheet 21 in the upper collet lifting process (step S25), as described above, at step S24, adhesive sheet 21 is sucked to concavity 48a by lower collet 40a and fluid FL is injected between adhesive sheet 21 and chip 23 by needle 44a. As such, adhesive sheet 21 is detached from the portion of chip 23 opposite to concavity 48a. Therefore, the adhesion area of chip 23 and adhesive sheet 21 at the time of initiating the upper collet lifting process (step S25) may be reduced. Thus, the detaching force F in the upper collet lifting process (step S25) can be reduced, and the time required for detaching, t, can be shortened.

In addition, also in the modified example, a size L2 of an opening 48aK of concavity 48a is set to be larger than a predetermined value where shear stress τ acting on chip S23 in the upper collet lifting process (step S25) becomes equal to the shear fracture strength (shear strength). In addition, size L2 of opening 48aK of concavity 48a may be set to be smaller than the plan view size L1 of chip 23. As a result, it is possible to suppress chip 23 from being pressured when chip 23 adhered to adhesive sheet 21 is picked up.

Further, the estimation of shear stress τ expressed by Equation 7 may also be applied to the modified example. Accordingly, when thickness d of chip 23 is thin, shear stress τ expressed by Equation 7 may be reduced by adjusting size L2 of opening 48aK of concavity 48a to be increased. In this manner, even when chip 23 with a thin thickness is picked up, it is possible to suppress chip 23 from being fractured.

Although exemplary embodiments have been described above, the present invention may be variously modified and changed within the scope of gist of the present invention defined in the claims, rather than being limited to such specific exemplary embodiments.

The international application claims priority right based on Japanese Patent Application No. 2010-194619 filed on Aug. 31, 2010, the disclosure of which is incorporated herein in its entirety by reference.

### DESCRIPTION OF REFERENCE NUMERALS

10, 10a: Pickup device
30: Upper collet
32: Upper collet driving mechanism
40, 40a: Lower collet
42, 42a: Lower collet driving mechanism
44, 44a: Needle
44T, 44aT: Tip end of needle
45S, 45aS: Top surface of lower collet upper end portion
48, 48a: Concavity
48K, 48aK: Opening of concavity
49, 49a: Bottom surface of concavity
51: Opening formed in bottom surface of concavity
57: Vibration unit

1. A pickup method comprising:
causing a first suction unit to approach and come into contact with a chip adhered to an adhesive sheet, and causing a second suction unit, which is formed with a concavity on a contact surface configured to come into contact with the adhesive sheet, to approach and come into contact with the adhesive sheet in such a manner as to be opposite to the first suction unit;
detaching the adhesive sheet from a portion of the chip opposite to the concavity by sucking the adhesive sheet by the second suction unit that is in contact with the adhesive sheet, and by injecting a fluid between the adhesive sheet and the chip by an injection unit; and
detaching and picking up the chip from the adhesive sheet by causing the first suction unit to be spaced away from the adhesive sheet that is being sucked by the second suction unit in the state where the chip is being sucked by the first suction unit.

2. The pickup method of claim 1, wherein the size of an opening of the concavity in the second suction unit is larger than a predetermined value where a shear stress acting on the chip when the first suction unit is caused to spaced away from the adhesive sheet becomes equal to the shear strength of the chip, and smaller than a plan view size of the chip.

3. The pickup method of claim 1, wherein, when detaching the adhesive sheet from the portion of the chip opposite to the concavity by sucking the adhesive sheet by the second suction unit that is in contact with the adhesive sheet, and by injecting the fluid between the adhesive sheet and the chip by the injection unit, the second suction unit sucks the adhesive sheet and a vibration unit vibrates the adhesive sheet, thereby initiating the detaching of the adhesive sheet from the portion of the chip opposite to the concavity, and the injection unit is inserted between the detaching initiated adhesive sheet and the chip to inject the fluid, thereby detaching the adhesive sheet from the portion of the chip opposite to the concavity.

4. The pickup method of claim 1, wherein the second suction unit is formed with an opening in the bottom surface of the concavity which is communicated with a suction bore that sucks the adhesive sheet, and
the injection unit is installed such that the tip end of the injection unit freely protrudes from the opening through the suction bore.

5. The pickup method of claim 1, wherein the injection unit is installed integrally with the second suction unit in the state where the tip end of the injection unit protrudes from the bottom surface of the concavity.

6. A pickup device comprising:
a first suction unit that sucks a chip;
a first driving unit that drives the first suction unit to be moved;
a second suction unit that is formed with a concavity on a contact surface configured to contact with an adhesive sheet, and sucks the adhesive sheet;
an injection unit that injects a fluid; and
a controller,
wherein the controller causes, by the first driving unit, the first suction unit to approach and come into contact with a chip adhered to an adhesive sheet, and causes, by the second driving unit, the second suction unit to approach and come into contact with the adhesive sheet in such a manner as to be opposite to the first suction unit,
the controller causes the second suction unit which is in contact with the adhesive sheet to suck the adhesive sheet, and the injection unit to inject the fluid between the adhesive sheet and the chip, thereby detaching the adhesive sheet from the portion of the chip opposite to the concavity, and
the controller causes, by the first driving unit, the first suction unit to be spaced away from the adhesive sheet which is being sucked by the second suction unit in the state where the first suction unit is sucking the chip, thereby detaching and picking up the chip from the adhesive sheet.

7. The pickup device of claim 6, wherein the size of an opening of the concavity in the second suction unit is larger than a predetermined value where a shear stress acting on the chip when the first suction unit is caused to spaced away from the adhesive sheet becomes equal to the shear strength of the chip, and smaller than a plan view size of the chip.

8. The pickup device of claim 6, further comprising a vibration unit,
wherein the controller causes the second suction unit to suck the adhesive sheet and the vibration unit to vibrate the adhesive sheet, thereby initiating the detaching of the adhesive sheet from the portion of the chip opposite to the concavity, and causes the injection unit to be inserted between the detaching initiated adhesive sheet and the chip to inject the fluid, thereby detaching the adhesive sheet from the portion of the chip opposite to the concavity.

9. The pickup device of claim 6, wherein the second suction unit is formed with an opening in the bottom surface of the concavity which is communicated with a suction bore that sucks the adhesive sheet, and
the injection unit is installed such that the tip end of the injection unit freely protrudes from the opening through the suction bore.

10. The pickup device of claim 6, wherein the injection unit is installed integrally with the second suction unit in the state where the tip end of the injection unit protrudes from the bottom surface of the concavity.
